(19) United States
(12) Patent Application Publication
(10) Pub. No.: US 2026/0013089 A1
(43) Pub. Date: Jan. 8, 2026

(54) NOISE FILTER

(71) Applicant: FANUC CORPORATION, Minamitsuru-gun, Yamanashi (JP)

(72) Inventor: Hiroki SUGIURA, Minamitsuru-gun, Yamanashi (JP)

(73) Assignee: FANUC CORPORATION, Minamitsuru-gun, Yamanashi (JP)

(21) Appl. No.: 18/879,947

(22) PCT Filed: Oct. 20, 2022
(86) PCT No.: PCT/JP2022/039162

§ 371 Date: Dec. 30, 2024

(51) Int. Cl. H05K 7/20; H03H 7/01; H03H 7/54

(52) U.S. Cl. CPC H05K 7/20909; H03H 7/0115; H03H 7/54

(57) ABSTRACT

A noise filter includes a capacitor, an inductor, a sealed unit that contains the capacitor, and an unsealed unit that contains the inductor and is at least partially open to outside air. The noise filter may be connected to a power conversion device, for example, a motor drive device, via a connector.

### TECHNICAL FIELD

The present disclosure relates to a noise filter.

### BACKGROUND ART

When a power conversion device, such as a motor drive device, is operated, high-frequency noise is generated from the built-in switching elements. In order to remove the high-frequency noise, a filter, such as a noise filter, is provided at the input part of the power conversion device. Such a noise filter comprises a capacitor and an inductor (for example, Japanese Unexamined Patent Publication (Kokai) No. 2021-121143).

### CITATION LIST

### Patent Literature

PTL1: Japanese Unexamined Patent Publication (Kokai) No. 2021-121143

### SUMMARY OF INVENTION

### Technical Problem

Though the heat generated by the capacitor during use of the noise filter is relatively small, the capacitor often contains flammable materials such as electrolytic paper, plastic film, and insulating oil. Furthermore, in capacitors which have structural parts comprising thin metal films, such as evaporated electrode films and metallicon electrodes, the metal oxidizes due to the external temperature and humidity, whereby the performance of the capacitor deteriorates over time. Thus, when the inductor generates heat inside the noise filter and the effect of this heat extends to the capacitor for a long period of time, the capacitor may break down and, in the worst case, ignite.

Thus, there is a demand for noise filters that are safe and easy to maintain.

### Solution to Problem

According to a first aspect of the present disclosure, there is provided a noise filter comprising a capacitor, an inductor, a sealed part in which the capacitor is accommodated, and an unsealed part in which the inductor is accommodated and which is at least partially open to outside air.

The object, features, and advantages of the present disclosure will become more apparent from the following description of the embodiments in conjunction with the accompanying drawings.

### BRIEF DESCRIPTION OF DRAWINGS

FIG. 1 is a perspective view of a noise filter according to a first embodiment.

FIG. 2 is an exploded perspective view of the noise filter shown in FIG. 1.

FIG. 3A is a cross-sectional view of a noise filter according to a modification example.

FIG. 3B is a cross-sectional view of a noise filter according to another modification example.

FIG. 4A is a perspective view of a noise filter according to a second embodiment.

FIG. 4B is a perspective view of a noise filter according to a third embodiment.

FIG. 4C is a perspective view of a noise filter according to a fourth embodiment.

FIG. 4D is a perspective view of a noise filter according to a fifth embodiment.

### DESCRIPTION OF EMBODIMENTS

The embodiments of the present disclosure will be described below with reference to the accompanying drawings. In the drawings, corresponding constituent elements have been assigned common reference signs.

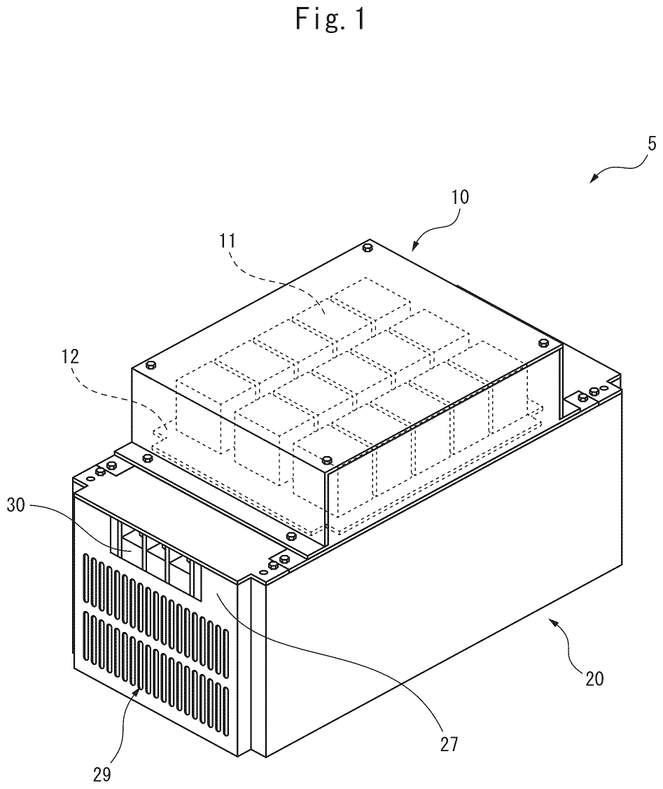

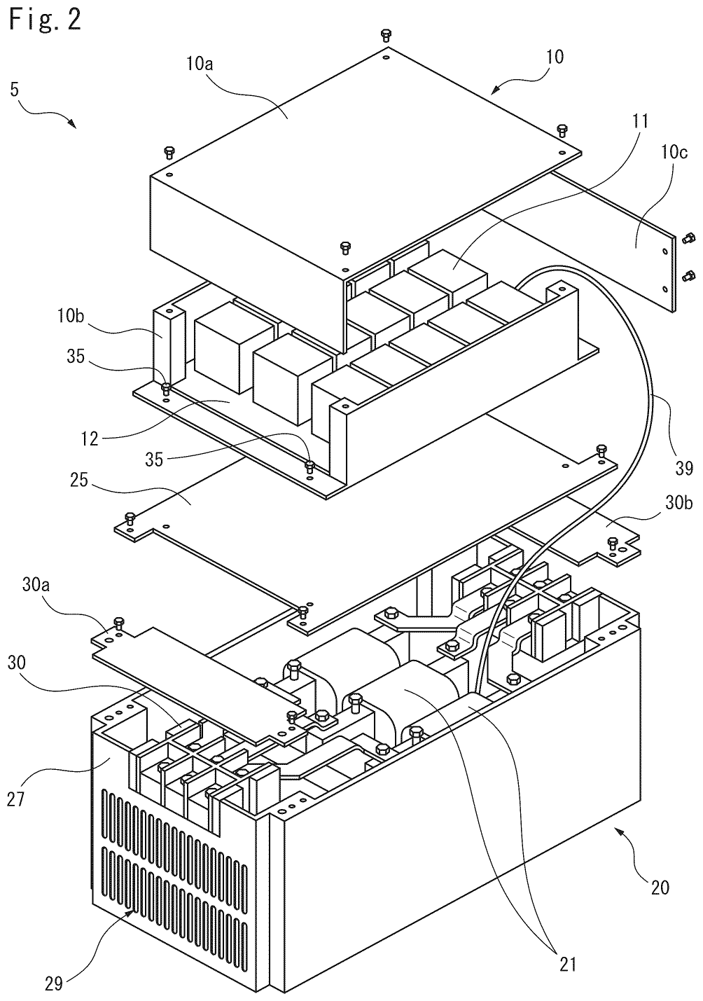

FIG. 1 is a perspective view of a noise filter according to a first embodiment, and FIG. 2 is an exploded perspective view of the noise filter shown in FIG. 1. As shown in these drawings, the noise filter 5 is an LC filter primarily comprising a capacitor 11 and an inductor 21. The noise filter 5 is connected to a power conversion device, for example, a motor drive device, via a connector 30.

Though a plurality of capacitors 11 are arranged in series on a substrate 12 in FIGS. 1 and 2, the noise filter 5 may comprise a single capacitor. The number of capacitors 11 may be appropriately changed in accordance with the required capacitance. A typical capacitor 11 comprises two conductors (not illustrated) insulated by a dielectric.

In FIGS. 1 and 2, a plurality of inductors 21 are arranged in parallel. However, the noise filter 5 may comprise a single inductor. The inductor 21 primarily comprises a coil. A core composed of a magnetic material may be arranged at the center of the coil. In other words, the inductor 21 may be a reactor.

The capacitor 11 and the inductor 21 are electrically connected to each other by a connection part 39. The connection part 39 may be a flexible conductor, such as a conductive wire, or a rigid conductor, such as a bus bar. Typically, the connection part 39 comprises a resistor (not illustrated) between the capacitor 11 and the inductor 21. In other embodiments, the connection part 39 may be omitted to illustrate. Since the noise filter 5 comprising the capacitor 11 and the inductor 21 is well known, additional explanation thereof has been omitted.

As shown in FIGS. 1 and 2, the capacitor 11 is accommodated in a sealed part 10. Though the sealed part 10 is preferably a rectangular parallelepiped as shown in the drawings, it may have other shapes, such as a cylindrical shape. The sealed part 10 is preferably composed of a flame-retardant material, such as a metal. However, the sealed part 10 may be composed of a resin to which an organic or inorganic flame retardant is added.

The sealed part 10 does not have a communication part, such as an opening, a notch, a valve, etc., which communicates the interior space of the sealed part 10 with the external space. It is preferable that the boundary parts of the adjacent outer surfaces of the sealed part 10 be sealed with a seal or the like, but sealing is not necessarily indispensable.

The connection part 39 is connected to the capacitor 11 via a hole (not illustrated) formed in the sealed part 10. The dimensions of the hole formed in the sealed part 10 are as sufficient as necessary to allow the connection part 39 to pass therethrough. The space between the hole and the connection part 39 may be sealed.

The inductor 21 is accommodated in an unsealed part 20. Though the unsealed part 20 is preferably a rectangular parallelepiped, it may have other shapes, such as a cylindrical shape. At least one opening 29 is formed in the unsealed part 20. Thus, the interior space and the external space of the unsealed part 20 communicate with each other through the opening 29. The unsealed part 20 is preferably formed from the same material as the sealed part 10.

In FIGS. 1 and 2, the opening 29 is formed in one end surface 27 of the unsealed part 20. However, other openings 28 and the like may be formed in other surfaces of the unsealed part 20, such as other end surface 26 and the side surfaces. Alternatively, the opening 29 may be formed in a portion of the upper surface of the unsealed part 20 where the sealed part 10 is not arranged.

As can be understood from FIG. 2, a plate-like part 25 is arranged horizontally between the sealed part 10 and the unsealed part 20. The plate-like part 25 may be composed of the same material as the sealed part 10, or the plate-like part 25 may be composed of a thermally-insulating material. As shown in the drawing, the plate-like part 25 may serve as a lid for the unsealed part 20 together with covers 30a, 30b for the connector 30. The covers 30a, 30b are also composed of the same material as the sealed part 10.

The sealed part 10 and the unsealed part 20 are preferably affixed to each other by fixation implements 35, such as screws. In FIG. 2, a flange portion of the sealed part 10 is affixed to the unsealed part 20 including the plate-like part 25 by the fixation implements 35. Each of the sealed part 10 and the unsealed part 20 is preferably constructed so as to be replaceable.

The capacitor 11 of the noise filter 5 of the present disclosure is accommodated in the sealed part 10 and the inductor 21 is accommodated in the unsealed part 20 in this manner. When a power conversion device, for example, a motor drive device, is driven, high-frequency noise is generated from the switching elements of the power conversion device. The noise filter 5 connected to the power conversion device functions to eliminate high-frequency noise.

The capacitor 11 may deteriorate over time due to the power conversion device itself, and the temperature of the capacitor may rise due to self-heating. Furthermore, the metal electrodes inside the capacitor 11 may oxidize due to the influence of the heat of the inductor 21 of the noise filter 5 and the humidity of the outside air, whereby the characteristics of the capacitor may deteriorate, and as a result, the temperature of the capacitor may rise due to self-heating. The capacitor 11 may comprise a laminate of electrolytic paper or plastic film and metal foil, or a metallized film in which metal is evaporated onto a plastic film. In large capacitors, such a laminate or metallized film is often impregnated with electrical insulating oil. Specifically, the capacitor 11 may comprise multiple types of flammable materials. In such a case, the deterioration of the capacitor 11 may be accelerated due to the influence of the heat of the inductor 21, and in the worst case, the flammable material of the capacitor 11 may ignite.

In the present disclosure, the capacitor 11 is sealed by the sealed part 10. Specifically, the capacitor 11 is isolated from the inductor 21 in the unsealed part 20. Thus, the capacitor 11 in the sealed part 10 is less susceptible to the heat of the inductor 21.

Even if the flammable material of the capacitor 11 ignites, since the capacitor 11 is accommodated in the sealed part 10, the effects of the ignition of the capacitor 11 is unlikely to reach the inductor 21.

Thus, even if the capacitor 11 in the sealed part 10 is damaged, there is little risk that the inductor 21 in the unsealed part 20 will become damaged. Accordingly, when the capacitor 11 is damaged, the fixation implements 35 are removed, the sealed part 10 including the capacitor 11 is separated from the unsealed part 20, and a new sealed part 10 having a similar configuration is assembled with the unsealed part 20.

From the foregoing, it will be understood that in the first embodiment, it is possible to significantly improve the safety of the noise filter 5 and also to improve maintainability of the noise filter 5.

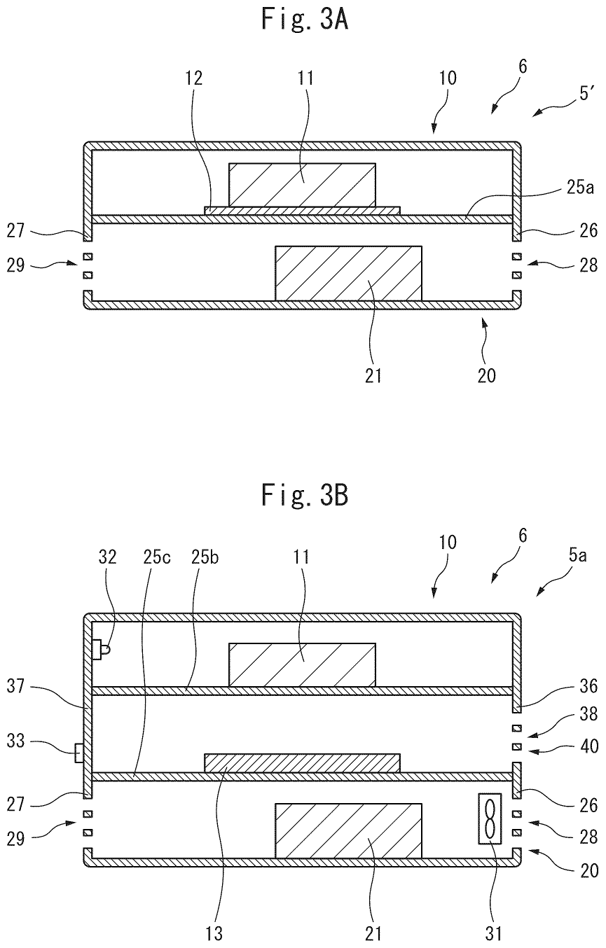

FIG. 3A is a cross-sectional view of a noise filter according to a modification example. The noise filter 5′ shown in FIG. 3A comprises a housing 6, and a plate-like part 25a arranged horizontally divides the interior space of the housing 6 into an upper portion and a lower portion. The upper portion of the housing 6 functions as the sealed part 10 in which the capacitor 11 and the like are arranged. Furthermore, the lower portion of the housing 6 functions as the unsealed part 20 in which the inductor 21 and the like are arranged. For this purpose, the opening 29 is formed in the end surface 27 of the lower portion of the housing 6.

In other words, the plate-like part 25a is a portion of the wall part constituting the sealed part 10 and is also a portion of the wall part constituting the unsealed part 20. The plate-like part 25a can serve as a partition plate for separating the sealed part 10 and the unsealed part 20 from each other in the housing 6. An opening 28 may be additionally formed in the end surface 26 of the lower portion of the housing 6. In the modification example shown in FIG. 3A, in addition to the above-mentioned effects, the sealed part 10 and the unsealed part 20 can be easily formed by simply arranging the plate-like part 25 in the housing 6 in which the opening 29 and the like are formed.

FIG. 3B is a cross-sectional view of a noise filter according to another modification example. In the noise filter 5a shown in FIG. 3B, two parallel plate-like parts 25b, 25c are arranged horizontally in the housing 6. The interior space of the housing 6 is divided into three by these plate-like parts 25b, 25c. The uppermost space functions as the sealed part 10 in which the capacitor 11 and the like are arranged. Furthermore, the lowermost space functions as the unsealed part 20 in which the inductor 21 and the like are arranged. For this purpose, the opening 29 is formed in the end surface 27 of the corresponding lower portion of the housing 6.

The intermediate space interposed between the plate-like parts 25b, 25c is an enclosure part 40 for isolating the capacitor 11 and the inductor 21 from each other. A control printed circuit board 13 for the noise filter 5a and the like are arranged in the enclosure part 40. The intermediate space shown in FIG. 3B is configured as an unsealed part, and an opening 38 is formed in a wall part 36 of the housing 6. However, the enclosure part 40 may be configured as a sealed part, and the opening 38 may not be formed.

In the modification example shown in FIG. 3B, the enclosure part 40 is arranged between the uppermost space in which the capacitor 11 is arranged and the lowermost space in which the inductor 21 is arranged. Since the enclosure part 40 itself has a thermally-insulating effect, even if the inductor 21 generates heat, the capacitor 11 in the sealed part 10 is less susceptible to the heat of the inductor 21. Likewise, it can be understood that even if the flammable material of the capacitor 11 ignites, the inductor 21 is less susceptible to the ignition of the capacitor 11. Thus, it is possible to further improve the safety of the noise filter 5a. The interior space of the enclosure part 40 may be filled with a thermally-insulating material.

In FIG. 3B, a sensor 32 as a detection part is further arranged in the interior space of the sealed part 10. The sensor 32 is a temperature sensor or a smoke sensor, and is connected to the control printed circuit board 13. When the sensor 32 detects that the temperature of the interior space of the sealed part 10 has reached a predetermined temperature or higher, or that smoke has been generated in the interior space of the sealed part 10, this information is output via an output unit 33. The output unit 33 may be a lamp or a speaker provided on the outer surface of the noise filter 5. Alternatively, an operation screen of an NC device for controlling the power conversion device, such as a motor drive device, to which the noise filter 5 is connected may be used as the output unit 33 to display the above-mentioned information.

The output unit 33 is preferably provided at a location other than the sealed part 10, for example, on the outer surface of the unsealed part 20, or on the outer surface of the enclosure part 40 as shown in FIG. 3B. When the capacitor 11 in the sealed part 10 is damaged by heat, it is sufficient to separate the entire sealed part 10, assemble a new sealed part 10, and connect a signal line (not illustrated) extending from the output unit 33 to the sensor 32. Thus, even if the capacitor 11 of the sealed part 10 is damaged, it is possible to prevent the output unit 33 provided at a location other than the sealed part 10 from becoming damaged.

The above-mentioned predetermined temperature is, for example, a value lower than the ignition temperature of the flammable material contained in the capacitor 11 by a predetermined temperature. Since the sensor 32 is provided, it is possible to recognize in advance that the capacitor 11 may ignite and to issue a warning to the outside via the output unit 33. Thus, it is possible to prevent the capacitor 11 from actually igniting.

In FIG. 3B, a fan 31 is arranged on the end surface 26 side of the housing 6 in the interior space of the unsealed part 20. The fan 31 draws external air into the interior space of the unsealed part 20 through the opening 28 of the end surface 26, cools the inductor 21, and exhausts the air from the opening 29 of the other end surface 27. Since the inductor 21 can be air-cooled by the fan 31, the effect of heat on the capacitor 11 can be reduced. Naturally, the fan 31 can be arranged in the noise filter of other embodiments.

In this regards, there may occur a situation in which the capacitor ignites while the inductor is being air-cooled by the fan. When such a situation occurs in the prior art, since the capacitor is not accommodated in a sealed part, flames generated in the capacitor are blown inside the noise filter by the fan. As a result, the inductor may be overheated by the flames and may become damaged. Furthermore, the flames may extend to the outside of the noise filter through an opening (corresponding to opening 29) in the end face where the fan is not arranged, which may cause the flames to spread to objects arranged around the noise filter.

However, since the capacitor 11 is accommodated in the sealed part 10 in the present disclosure, even if the capacitor 11 ignites, the flames will not reach the inductor 21 arranged in the interior space of the unsealed part 20. Furthermore, since the flames do not reach the interior space of the unsealed part 20, the fan 31 will not cause the flames to spread to the outside of the noise filter 5 through the opening 29. Specifically, even if the noise filter 5 includes the fan 31 inside the unsealed part 20, a situation in which the flames spread to objects arranged around the noise filter 5 will not occur. Thus, even if the fan 31 is included, a highly safe noise filter 5 can be provided.

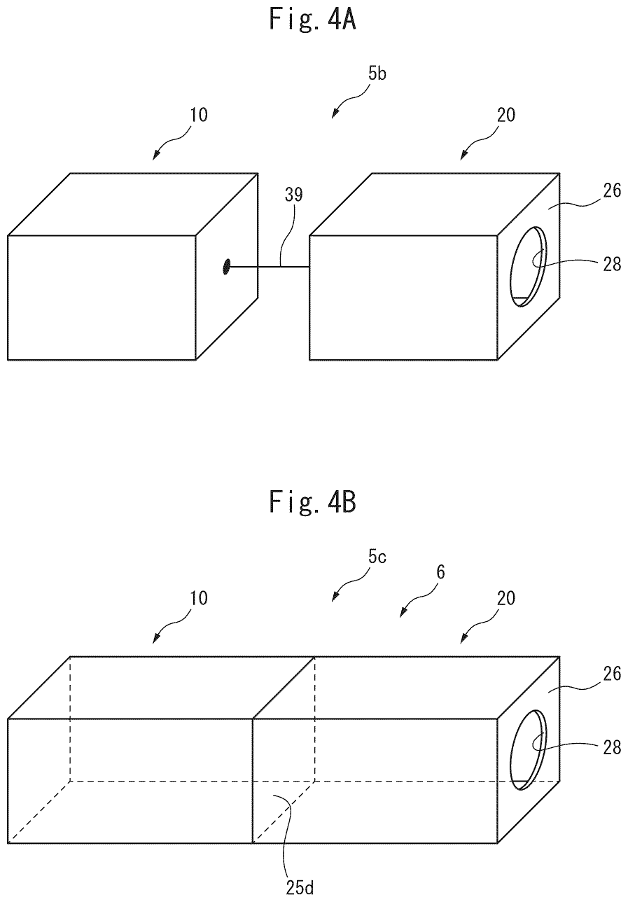

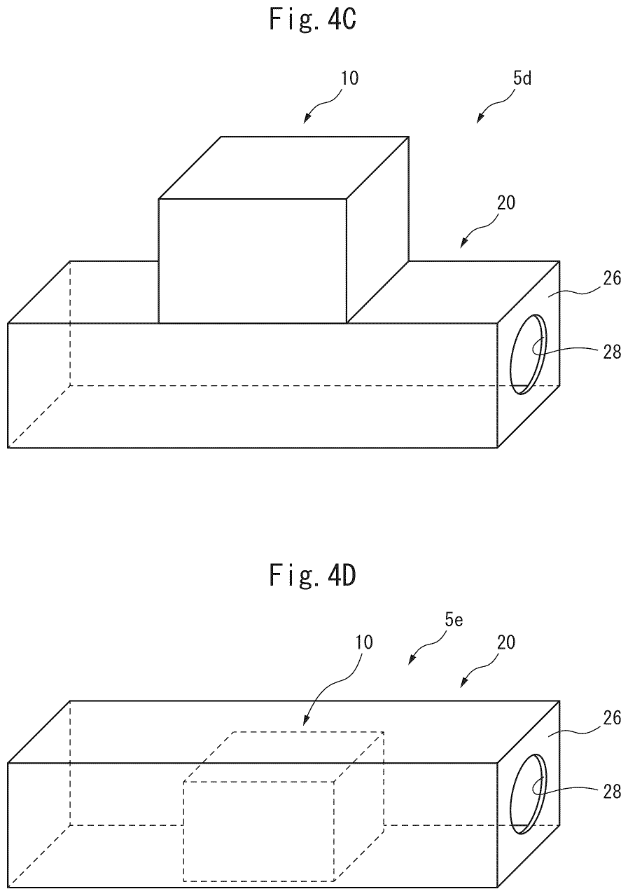

FIG. 4A is a perspective view of a noise filter according to a second embodiment. The connection part 39 of the second embodiment is a flexible conductor, for example, a wire. Thus, in the second embodiment, the positional relationship between the sealed part 10 and the unsealed part 20 can be freely changed within the range of the length of the connection part 39 (conductive wire). Accordingly, the arrangement of the entire noise filter 5b can be flexibly changed in accordance with the environment in which the power conversion device and the like are arranged.

For example, when only a long and narrow space can be secured, the sealed part 10 and the unsealed part 20 may be arranged so as to be in series in the horizontal direction, as shown in FIG. 4A. In a space where the height direction is relatively long and horizontal distance cannot be secured sufficiently, the sealed part 10 and the unsealed part 20 may be arranged so as to be stacked on top of each other (refer to FIG. 1, etc.). Alternatively, in an environment where there is a step, though not illustrated in the drawings, the sealed part 10 may be arranged above the step, and the unsealed part 20 may be arranged below the step.

FIG. 4B is a perspective view of a noise filter according to a third embodiment. A plate-like part 25d extending in the vertical direction is arranged in the housing 6 of the noise filter 5c shown in FIG. 4B. Though the plate-like part 25d is arranged in the center of the horizontal width of the housing 6 in FIG. 4B, the plate-like part 25d may be arranged in a location other than the center.

The left portion of the housing 6 functions as the sealed part 10 in which the capacitor 11 and the like are arranged. Furthermore, the right portion of the housing 6 functions as the unsealed part 20 in which the inductor 21 and the like are arranged. For this purpose, the opening 28 is formed in the end surface 26 of the lower portion of the housing 6. In other words, the plate-like part 25d is a portion of the wall part constituting the sealed part 10 and is also a portion of the wall part constituting the unsealed part 20.

The configuration shown in FIG. 4B is a modification example of the configuration shown in FIG. 3A. Thus, the same effects as those described in relation to FIG. 3A can be obtained. In the third embodiment, two parallel plate-like parts 25 may be arranged vertically in the housing 6, with the rightmost portion serving as the sealed part 10, the leftmost portion serving as the unsealed part 20, and the middle portion serving as the enclosure part 40 described above.

FIG. 4C is a perspective view of a noise filter according to a fourth embodiment. In the noise filter 5d shown in FIG. 4C, the sealed part 10 is arranged so as to be stacked on the unsealed part 20. In this configuration, the bottom wall part of the sealed part 10 may be shared with the upper wall part of the unsealed part 20. The sealed part 10 may be arranged at a corner of the upper surface of the unsealed part 20.

FIG. 4D is a perspective view of a noise filter according to a fifth embodiment. In the noise filter 5e shown in FIG. 4D, the sealed part 10 is arranged in the interior space of the unsealed part 20. In this configuration, the wall part on the bottom side of the sealed part 10 may be shared with the wall part on the bottom side of the unsealed part 20. Furthermore, a configuration in which the unsealed part 20 is arranged in the interior space of the sealed part 10 may be adopted.

The interior space of the sealed part 10 may be at least partially filled with a resin, for example, a flame-retardant resin. As a result, the amount of oxygen in the interior space of the sealed part 10 is reduced, thereby reducing the risk of ignition of the capacitor 11 in the sealed part 10.

At least one of the embodiments and modification examples described above has the effect of significantly improving the safety of the noise filter 5 and improving the maintainability of the noise filter 5.

Though the embodiments of the present disclosure have been described in detail, the present disclosure is not limited to the individual embodiments described above. Various additions, replacements, modifications, partial deletions, etc., can be made to these embodiments within the scope of the spirit of the invention, or within the scope of the idea and intent of the present invention derived from the contents described in the claims and their equivalents. For example, though the order of each operation and the order of each process are shown as examples in the above-mentioned embodiments, the present invention is not limited to these. The same applies when numerical values or formulas are used in the description of the above-mentioned embodiments. Furthermore, appropriate combinations of some of the above-mentioned embodiments are included in the scope of the present disclosure.

The following addendums are further disclosed in relation to the embodiments and modification examples described above.

### Addendum 1

A noise filter, comprising:
a capacitor,
an inductor,
a sealed part in which the capacitor is accommodated, and
an unsealed part in which the inductor is accommodated and which is at least partially open to outside air.

### Addendum 2

The noise filter according to Addendum 1, wherein the capacitor comprises a flammable material.

### Addendum 3

The noise filter according to Addendum 1 or 2, further comprising a connection part for electrically connecting the capacitor and the inductor, wherein the connection part is a wire.

### Addendum 4

The noise filter according to any one of Addendums 1 to 3, comprising a detection part, which is provided in the sealed part, for detecting a state of an interior space of the sealed part.

### Addendum 5

The noise filter according to any one of Addendums 1 to 4, wherein the noise filter comprises a housing, and the sealed part and the unsealed part are formed by partitioning an interior space of the housing with a partition.

### Addendum 6

The noise filter according to any one of Addendums 1 to 5, wherein an interior space of the sealed part is filled with a resin.

### Addendum 7

The noise filter according to any one of Addendums 1 to 6, wherein at least a portion of a wall part of the sealed part is shared with a wall part of the unsealed part.

### Addendum 8

The noise filter according to any one of Addendums 1 to 7, further comprising a fan, which is arranged in the unsealed part, for cooling the interior space of the unsealed part.

### REFERENCE SIGNS LIST

5, 5′, 5a to 5e noise filter
6 housing
10 sealed part
11 capacitor
12 substrate
13 control printed circuit board
20 unsealed part
21 inductor
25, 25a to 25d plate-like part
28, 29, 38 opening
31 fan
32 sensor (detection part)
35 fixation implement
39 connection part
40 enclosure part

1. A noise filter, comprising:
a capacitor,
an inductor,
a sealed part in which the capacitor is accommodated, and
an unsealed part in which the inductor is accommodated and which is at least partially open to outside air.

2. The noise filter according to claim 1, wherein the capacitor comprises a flammable material.

3. The noise filter according to claim 1, further comprising a connection part for electrically connecting the capacitor and the inductor, wherein
the connection part is a wire.

4. The noise filter according to claim 1, comprising a detection part, which is provided in the sealed part, for detecting a state of an interior space of the sealed part.

5. The noise filter according to claim 1, wherein the noise filter comprises a housing, and
the sealed part and the unsealed part are formed by partitioning an interior space of the housing with a partition.

6. The noise filter according to claim 1, wherein an interior space of the sealed part is filled with a resin.

7. The noise filter according to claim 1, wherein at least a portion of a wall part of the sealed part is shared with a wall part of the unsealed part.

8. The noise filter according to claim 1, further comprising a fan, which is arranged in the unsealed part, for cooling the interior space of the unsealed part.
